(19) United States
(12) Patent Application Publication
(10) Pub. No.: US 2011/0303016 A1
(43) Pub. Date: Dec. 15, 2011

(54) FLEXIBLE POLYMER-BASED ENCAPSULATED-FLUID DEVICES

(75) Inventors: Christian A. Gutierrez, Los Angeles, CA (US); Ellis Meng, Alhambra, CA (US)

(73) Assignee: UNIVERSITY OF SOUTHERN CALIFORNIA, Los Angeles, CA (US)

(21) Appl. No.: 13/202,882

(22) PCT Filed: Feb. 24, 2010
(86) PCT No.: PCT/US2010/025248

§ 371 Date: Aug. 23, 2011

Related U.S. Application Data
(60) Provisional application No. 61/154,959, filed on Feb. 24, 2009.
(60) Provisional application No. 61/246,892, filed on Sep. 29, 2009.
(60) Provisional application No. 61/246,891, filed on Sep. 29, 2009.

(51) Int. Cl. G01L 9/02; G01R 27/08

(52) U.S. Cl. 73/719; 324/722; 205/687

(57) ABSTRACT

Embodiments of the present disclosure are directed to MEMS-based medical devices including a flexible housing that forms a chamber for encapsulating a fluid or liquid. The devices also include encapsulated electrodes, portions of which are exposed to the fluid or liquid within the chamber for sensing and/or physical actuation (controlled movement). Such medical devices can function specifically as: contact force sensors; and/or out-of-plane actuators. Device function is enabled by the encapsulation of liquid within the microchamber. Depending on the kind of electrical input applied, the encapsulated electrodes can function as electrochemical sensing elements; and/or electrolytic generation electrodes. Devices according to the present disclosure can have a fluidic coupling to the external environment or can be isolated. Fluidic isolation from the surrounding environment can be accomplished by the inclusion of an annular-plate stiction valve within the device. Related methods of use and fabrication are also described.

### CROSS-REFERENCE TO RELATED APPLICATIONS

This application is based upon and claims priority to the following: U.S. Provisional Patent Application No. 61/154,959, entitled “FLEXIBLE PARYLENE-BASED ELECTRO-MECHANICAL INTERFACE TECHNOLOGY FOR NEURAL PROSTHESES,” filed Feb. 24, 2009, attorney docket USCST-004N; U.S. Provisional Patent Application No. 61/246,891, entitled “AUTOMATIC LIQUID ENCAPSULATION IN PARYLENE MICROCHAMBERS BY INTEGRATED STICTION VALVES,” filed Sep. 9, 2009, attorney docket USCST-007N; and U.S. Provisional Patent Application No. 61/246,892, entitled “MEMS FORCE/TACTILE SENSORS BASED ON TRANSDUCTION OF ENCAPSULATED LIQUID WITHIN PARYLENE MICROSTRUCTURES,” filed Sep. 9, 2009, attorney docket USCST-008N.

The entire content of all of these applications is incorporated herein by reference.

### STATEMENT REGARDING FEDERALLY SPONSORED RESEARCH

This invention was made with Government support under Contract No. EEC-0310723 awarded by the National Science Foundation (NSF), and Contract No. ECS-0547544 awarded by the National Science Foundation (NSF). The Government has certain rights in the invention.

### BACKGROUND

1. Technical Field

This disclosure relates to micro electro mechanical systems (MEMS), including medical devices that encapsulate a fluid or liquid, and related sensor and actuation devices.

2. Description of Related Art

Many microelectromechanical systems (MEMS) based medical devices utilize encapsulated liquids. Some examples include applications for variable-focus liquid lens optics, electrolysis actuators, and electrowetting devices.

For such devices, stiction valves have been used to seal the liquid within the device chamber. Typically, the stiction valves have been placed externally in relation to the liquid chamber and active structures. Such an external valve configuration unnecessarily increases the overall footprint of the device. Attempts at integrating stiction valves within a device active structure have been shown to negatively affect long-term encapsulation due to leakage and poor valve design.

Other medical devices function as neural prostheses, with notable examples being intraocular prostheses and cortical prostheses. At the heart of every neural prosthesis there exists an interface between the tissue and the device structure. Most neural prosthesis function by recording/sensing neural output and/or stimulating tissue via microelectrodes.

Generally, the efficacy of an electronic neural prosthesis, such as an intraocular retinal prosthesis, is highly dependent on the electromechanical coupling or interface between the device and tissue. Factors such as proximity, temperature, pressure, and post-implantation small-scale motion all play an important role to the overall function of a neural prosthesis. Previous techniques have not adequately addressed such factors.

Many contact sensor transduction methods have been explored (piezoresistive, capacitive, conductive polymers, optical, and ultrasound). However, large sensor footprints have precluded their use in device-tissue interfaces.

### SUMMARY

Aspects of the present disclosure are directed to devices based on microelectromechanical systems (MEMS), including medical devices that utilize flexible housings or chambers to encapsulate liquid and function as sensors and/or actuation devices. Exemplary embodiments of the present disclosure can include a flexible MEMS encapsulated-liquid medical device including a flexible housing having an interior surface defining a chamber and configured to encapsulate a liquid within the chamber; first and second fluidic access ports configured to admit liquid into the chamber; and first and second electrodes, each having a portion exposed to the chamber, in which the first and second electrodes are configured to sense an impedance of a liquid within the chamber.

The device can include a stiction valve configured to seal the chamber.

The housing of the device can include Parylene.

The housing of the device can include Parylene C.

The first and second fluidic access ports can each include an internal and external aperture relative to the housing, in which the internal and external apertures are connected by an access port via.

The device housing can be cylindrical and can have a diameter from about 25 μm to about 1 mm, including any subrange of such.

The device housing can include a substrate and the stiction valve can include a valve plate with a central aperture, in which the central aperture is configured to admit liquid from the first and second fluidic access ports to the chamber when the valve plate is not in contact with the substrate.

Further exemplary embodiments of the present disclosure can include a flexible MEMS encapsulated-liquid medical device including a flexible housing having an interior surface defining a chamber and configured to encapsulate a liquid within the chamber; first and second fluidic access ports configured to admit liquid into the chamber; and first and second electrodes, each having a portion exposed to the chamber, and configured to cause electrolysis of a liquid within the chamber; and at least one electrode disposed on the exterior surface of the housing.

The at least one electrode of the device can be configured as a plurality of electrodes.

The plurality of electrodes can be configured as a microelectrode array (MEA).

The device housing can include Parylene.

The device housing can include Parylene C.

The device can include a stiction valve configured to seal the chamber.

The first and second fluidic access ports can each include an internal and external aperture relative to the housing, in which the internal and external apertures are connected by an access port via.

The device housing can be cylindrical and can have a diameter from about 25 μm to about 1 mm, including any subrange of such.

The device housing can include a substrate and the stiction valve can include a valve plate with a central aperture, in which the central aperture is configured to admit liquid from the first and second fluidic access ports to the chamber when the valve plate is not in contact with the substrate.

Further exemplary embodiments of the present disclosure can provide a method of positioning a surface relative to a medical device, where the medical device includes (i) a flexible housing having a substrate and an interior defining a chamber configured to encapsulate a liquid within the chamber, (ii) first and second electrodes, each having a portion exposed to the chamber, and (iii) and at least one electrode disposed on the exterior surface of the housing. The method can include applying a voltage potential across the first and second electrodes; causing electrolysis of a liquid within the chamber; and moving the exterior surface relative to the substrate.

For the method, the at least one electrode disposed on the exterior surface of the housing can be configured as a microelectrode array (MEA).

For method, the medical device can further include first and second fluidic access ports configured to admit liquid into the chamber.

For the method, the medical device can further include a stiction valve.

For the method, the housing of the medical device can include Parylene.

The method can further include encapsulating liquid within the chamber.

Further exemplary embodiments of the present disclosure can provide a method of sensing force applied to a movable surface of a medical device, where the medical device includes (i) a flexible housing having a substrate, a moveable surface, and an interior defining a chamber configured to encapsulate a liquid within the chamber, and (ii) first and second electrodes, each having a portion exposed to the chamber. The method can include applying a voltage potential across the first and second electrodes; in response to a force applied to the movable surface, sensing an impedance change of a liquid within the chamber; and correlating a sensed impedance change of the liquid to the force applied to the moveable surface.

For method, the medical device can further include first and second fluidic access ports configured to admit liquid into the chamber.

For the method, the medical device can further include a stiction valve.

For the method, the housing of the medical device can include Parylene.

The method can further include encapsulating liquid within the chamber.

These, as well as other components, steps, features, benefits, and advantages, will now become clear from a review of the following detailed description of illustrative embodiments, the accompanying drawings, and the claims.

### BRIEF DESCRIPTION OF DRAWINGS

The drawings disclose illustrative embodiments of the present disclosure. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same numeral appears in different drawings, it refers to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIG. 1 illustrates a medical device sensor coupled to an external fluidic environment, in accordance with exemplary embodiments of the present disclosure;

FIG. 2 illustrates a medical device sensor isolated from an external fluidic environment, in accordance with exemplary embodiments of the present disclosure;

FIG. 3 illustrates a medical device actuator coupled to an external fluidic environment, in accordance with exemplary embodiments of the present disclosure;

FIG. 4 illustrates a medical device actuator isolated from an external fluidic environment, in accordance with exemplary embodiments of the present disclosure;

FIG. 5 includes views (a) and (b), which depict a representation of an impedance-based force transduction technique for sensors, and a medical device equivalent circuit, in accordance with exemplary embodiments of the present disclosure;

FIG. 6 illustrates an out-of-plane actuator, in accordance with exemplary embodiments of the present disclosure;

FIG. 7 illustrates the principle of operation of a stiction valve integrated into a medical device, in accordance with exemplary embodiments of the present disclosure;

FIG. 8 is an optical photograph of device having a 300 μm diameter chamber and stiction valve, according to the present disclosure; and

FIG. 9 includes top and side-section views of a medical device microchamber with stiction valve, including the layout and key parameters, in accordance with exemplary embodiments.

While certain embodiments are depicted in the drawings, one skilled in the art will appreciate that the embodiments depicted are illustrative and that variations of those shown, as well as other embodiments described herein, may be envisioned and practiced within the scope of the present disclosure.

### DETAILED DESCRIPTION OF ILLUSTRATIVE EMBODIMENTS

Illustrative embodiments are now discussed. Other embodiments may be used in addition or instead. Details that may be apparent or unnecessary may be omitted to save space or for a more effective presentation. Conversely, some embodiments may be practiced without all of the details that are disclosed.

Embodiments of the present disclosure are directed to MEMS-based devices including a flexible housing that forms a chamber for encapsulating a fluid or liquid. The devices also include encapsulated electrodes, portions of which are exposed to the fluid or liquid within the chamber for sensing and/or physical actuation (controlled movement). Embodiments of such devices can function specifically as: contact force sensors; and/or out-of-plane actuators. Device function is enabled by the encapsulation of liquid within the microchamber. Depending on the kind of electrical input applied, the encapsulated electrodes can serve two functions: electrochemical sensing elements; and/or electrolytic electrodes, where portions of the electrodes function as a cathode and an anode for generating gas.

Whether configured as sensors or actuators, devices according to the present disclosure can have a fluidic coupling to the external environment or can be isolated. Fluidic isolation from the surrounding environment can be accomplished by the inclusion of an annular-plate stiction valve within the device. Such valves are activated by stiction and form a complete seal, thereby trapping the desired liquid within the microchamber of the devices.

Exemplary embodiments of such devices/structures can be configured and utilized as medical devices. In addition to medical uses, however, the structures, actuators, and sensors described herein also have many other applications including, but not limited to, the following: the positioning or manipulation of miniature objects (actuator uses), tactile feedback for interrogation of unknown surfaces having fine features (sensor uses), and cushioning of supported objects (structure uses). The individual structures, actuators, or sensors can be arrayed on a supporting substrate (which may be flexible or rigid) to create smart surfaces that allow multiple levels of interaction with the environment, as indicated above. For example, structures in accordance with the present disclosure can be used as sensors for robotic applications for tactile feedback and/or as actuators for fine-scale controlled movement/positioning. Examples of such, can include, but are not limited to use with surgical robots, military robots such as those used for bomb/IED confinement or destruction/mitigation, and robots used for under-water/aquatic applications. Moreover, such structures (sensors and/or actuators) can be used for virtual reality applications. For example, structures (e.g., functioning as sensors) according to the present disclosure can be used as feedback mechanisms for virtual reality programs/environments by translating movement of a user's body (e.g., as detected by use of a glove of other body-covering structure with attached sensors) into signals corresponding to body motion. The virtual reality program/environment can receive the signals and process/accommodate the indicated body motion of the user. Conversely, structures (functioning as actuators) can provide tactile feedback to the user by applying force to the user's skin/body in a controlled manner.

As was noted above, exemplary embodiments of the present disclosure can be utilized for contact force sensor applications. Such contact force sensors can provide a flexible, polymer-based, microscale sensor element capable of operating in wet environments, requiring no hermetic packaging and with the ability to measure microNewton forces. An example of a specific application is the measurement of contact forces between implanted neuroprosthetic devices and the soft tissue with which they are in contact with. Mechanical characterization of contact forces at these locations is difficult, if not impossible, with traditional sensing approaches especially when dealing with polymer-based neural prosthetic devices (such as an epiretinal prosthesis).

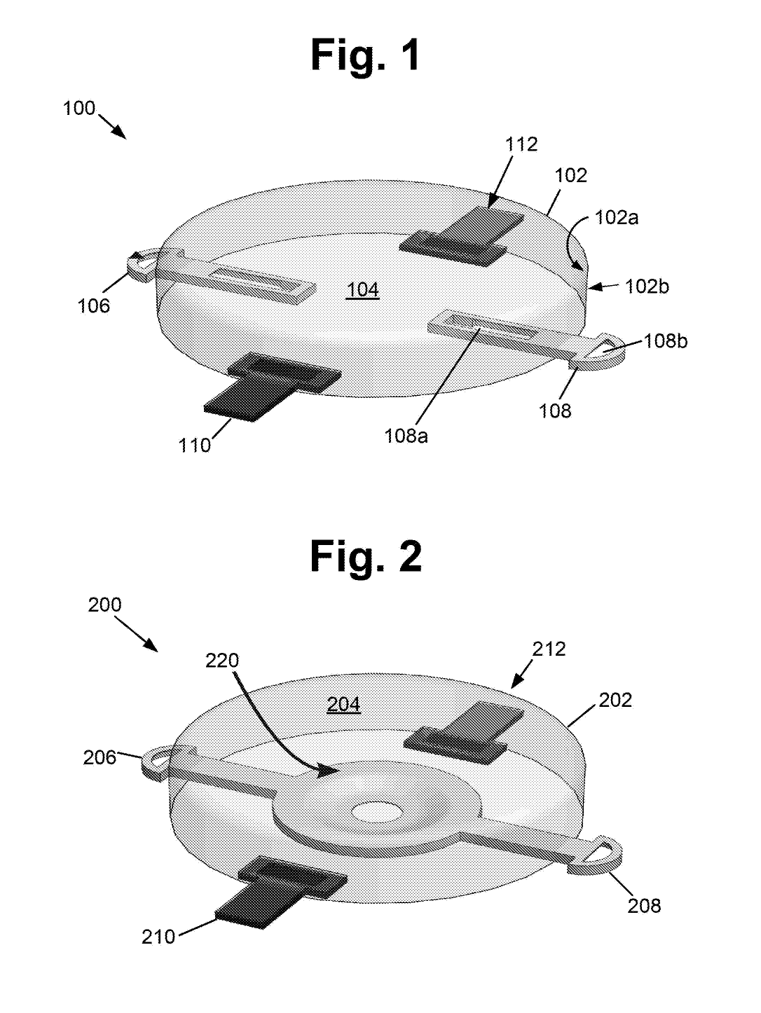

FIG. 1 illustrates a flexible MEMS medical device 100 configured as a sensor, according to exemplary embodiments of the present disclosure. The device 100 includes a flexible housing 102 having an interior surface or surfaces defining a chamber (or “microchamber”). Interior and exterior surfaces of housing 102 are indicated as 102a and 102b, respectively. The chamber is utilized to hold and encapsulate a fluid 104, e.g., a liquid. The device 100 includes fluidic access ports 106 and 108, which are structures located on the periphery of the device and allow fluids from the external environment to enter and fill the microchamber. The fluidic access ports 106, 108 provide a means of enabling fluid exchange between the microchamber and external environment without compromising the complete entrapment and structural integrity of the microchamber structure. As indicated, each fluidic access port, e.g., access port 108, can include internal and external apertures 108a, 108b relative to the housing/chamber 102. The internal and external apertures 108a and 108b are connected by an access port via or channel that functions to convey fluid into and/or out of the chamber 102.

In exemplary embodiments, Parylene C can be used as the housing material. Parylene C is a transparent thin-film biocompatible polymer that can be deposited at room temperature through a chemical vapor deposition process. Deposition is generally conformal and pin-hole free and exhibits excellent moisture barrier properties, good mechanical strength, electrical insulating properties, excellent chemical resistance and can be integrated with standard microfabrication techniques. Parylene C has a United States Pharmacopoeia (USP) Class VI biocompatibility standing required for implantable applications. For exemplary embodiments, the diameter of the chamber 102 can be selected as desired over a range of about 25 μm to about 1 mm, including any subrange of such.

With continued reference to FIG. 1, the device 100 also includes encapsulated electrodes, or portions of electrodes 110, 112, which are encapsulated or contained within the microchamber 102 and are exposed to the internal fluidic environment within the chamber. The electrodes 110, 112 can serve dual purposes: sensing, by measuring electrochemical impedance (solution resistance) which is correlated to the mechanical forces acting on the chamber; and/or, actuation (controlled movement) by application of sufficiently high current or potential across the electrodes to create an electrolytic reaction (producing gas) which generates high internal pressures within the chamber causing the surface to deform outward. Conductive non-metal materials may be used as an alternative to metals, though non-reactive metals such as platinum may be preferred for some applications.

As previously described, the fluid/liquid within a device microchamber can be isolated from fluid exterior to the medical device by integration of valve structure(s) within the device itself.

FIG. 2 illustrates a medical device sensor 200 isolated from an external fluidic environment by a stiction valve 220, in accordance with exemplary embodiments of the present disclosure. Similar to device 100 of FIG. 1, sensor 200 includes a flexible housing 202 having an interior defining a chamber for encapsulating a liquid 204, two fluidic access ports 206, 208 and two electrodes 210, 212. Integrated within the chamber and connected to the fluidic access ports is a stiction valve 220, with stiction being a term used to describe the effect of capillary forces exerted on two closely spaced surfaces during drying, especially during removal of sacrificial structures in standard MEMS processing. The strong capillary forces at the scale of medical devices according to the present disclosure can force the two surfaces together causing them to “stick”. Stiction valve 220 is a valve utilizing stiction as the sealing mechanism.

While the medical devices shown and described for FIGS. 1-2 are configured as sensors, medical devices in accordance with the present disclosure can have other functionality. As stated previously, exemplary embodiments of the present disclosure may be utilized for out-of-plane actuator applications. Such actuators can be used to move or position a device surface and/or tissue in a desired manner.

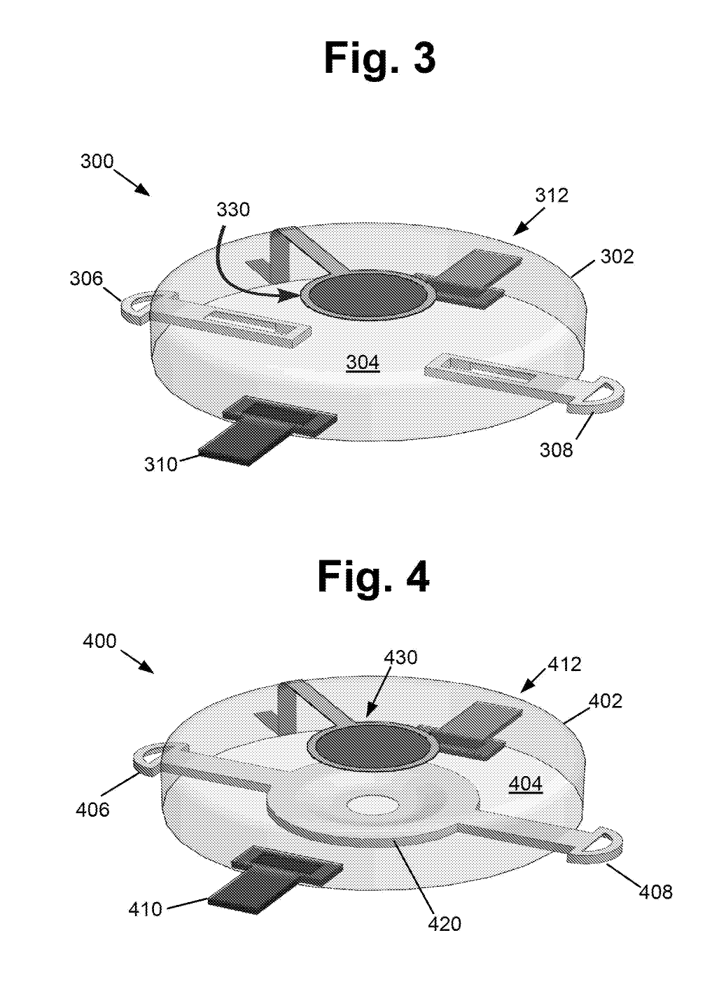

FIG. 3 illustrates a medical device actuator 300 coupled to an external fluidic environment, in accordance with exemplary embodiments of the present disclosure. Similar to the devices shown and described for FIGS. 1-2, actuator 300 includes a flexible housing 302 having an interior defining a chamber for encapsulating a liquid 304, two fluidic access ports 306, 308 and two electrodes 310, 312. Actuator 300, however, is configured as an out-of-plane electrochemical actuator and includes a microchamber 302 with a thin membrane capable of out-of-plane deflection when sufficient pressure is formed within the microchamber 302. The thin membrane of the chamber 302 can be made from a suitable polymer material, e.g., Parylene. Parylene is the generic name for members of a unique polymer series. The basic member of the series, called Parylene N, is poly-para-xylylene, a completely linear, highly crystalline material.

By application of sufficient voltage and/or current to the electrodes 310, 312, electrolysis of the liquid 304 can be caused to take place within the chamber 302. The integration of a device (such as an electrode or electrode array) on the thin top surface of the chamber/housing 302 can enable the out-of-plane actuation of such of a device. For example, FIG. 3 depicts an electrode 330 formed on top surface of the microchamber 302. The electrode 302 is exposed to the external environment. Electrode 330 can, instead of single electrode, be configured as multiple electrodes, e.g., as a microelectode array (MEA) that is part of a retinal (or other) implant.

Particular applications of such actuators (e.g., actuator 300) can be for the micropositioning of recording/stimulation electrodes for use with neural tissue both in-vivo and in-vitro. These actuators can ameliorate problems that have arisen for implanted neuroprosthetic devices that stimulate tissue. For example, there have been cases when the electrodes of such devices have separated from the target tissue. To enable more efficacious and targeted stimulation it is beneficial to reposition these electrodes closer to the tissue. An out-of-plane actuator according to the present disclosure is one way to accomplish this result. The integration of such technology is ideal for polymer-based neurostimulation platforms.

FIG. 4 illustrates a medical device actuator 400 isolated from an external fluidic environment by use of a stiction valve 420, in accordance with exemplary embodiments of the present disclosure. Actuator 400 is similar to the device shown and described for FIG. 2, with actuation occurring in a similar way as for device 300 of FIG. 3. MEMS actuator 400 includes a flexible housing 402 having an interior defining a chamber for encapsulating a liquid 404, two fluidic access ports 406, 408, two electrodes 410, 412, and a stiction valve 420.

The following description highlight features of exemplary embodiments of the present disclosure.

### A. Exemplary Embodiments

### Contact Force Sensing

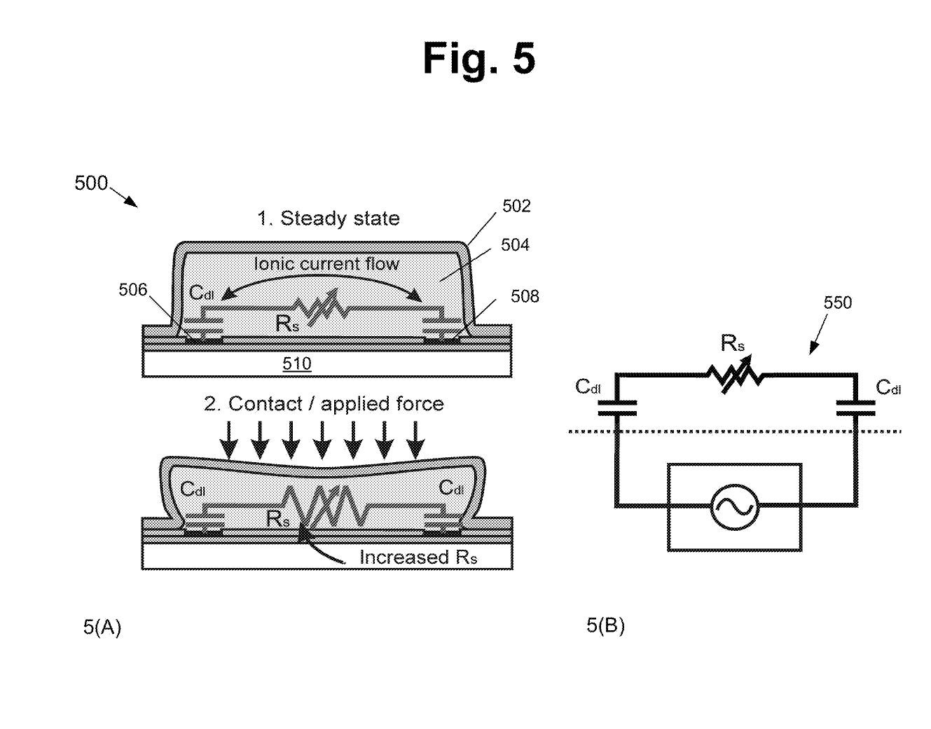

FIG. 5 includes views 5(A)-5(B), which depict a representation of an impedance-based force transduction technique for a flexible MEMS contact force sensor 500, and a medical device equivalent circuit, in accordance with exemplary embodiments of the present disclosure.

Sensor 500 consists of a microchamber 502 with a soft contact surface (Parylene C) and a pair of microelectrodes 506, 508 exposed to the contents (e.g., liquid 504) of the microchamber 502. Etched access ports (not shown) on the perimeter of the chamber 502 connect to an internal stiction valve (not shown) trapping fluid 504 within the cavity 502. The top portion of FIG. 5(A) shows sensor 500 in a steady state, without externally applied force/loading. Electrical characteristics of the device 500 for the steady state unloaded condition are indicated, where C_{dl} is the electrode double-layer capacitance and Rₛ is the solution resistance.

The lower portion of FIG. 5(A) shows that applied external forces deform the compliant fluid-filled structure 502 and redistribute the contained fluid 504. Alteration of the volumetric conductive path of current-carrying ions in the fluid registers as a change in solution impedance, as indicated by the increased value of the solution resistance Rₛ. Thus volumetric variations of an encapsulated liquid can be correlated to mechanical contact forces exerted by tissue or external sources on the sensor 500. FIG. 5(B) depicts an equivalent circuit of device 500.

### B. Exemplary Embodiments

### Actuators

To expand of features described above, actuation functionality can be accomplished in the same structure used for a sensor by simply applying a DC (or possibly AC) current or voltage potential across the encapsulated electrodes to generate hydrogen and oxygen gases. The resulting build-up of internal pressure within the chamber can cause the top membrane of the chamber to deform upwards. Such motion can be used advantageously as actuation for controlled positioning.

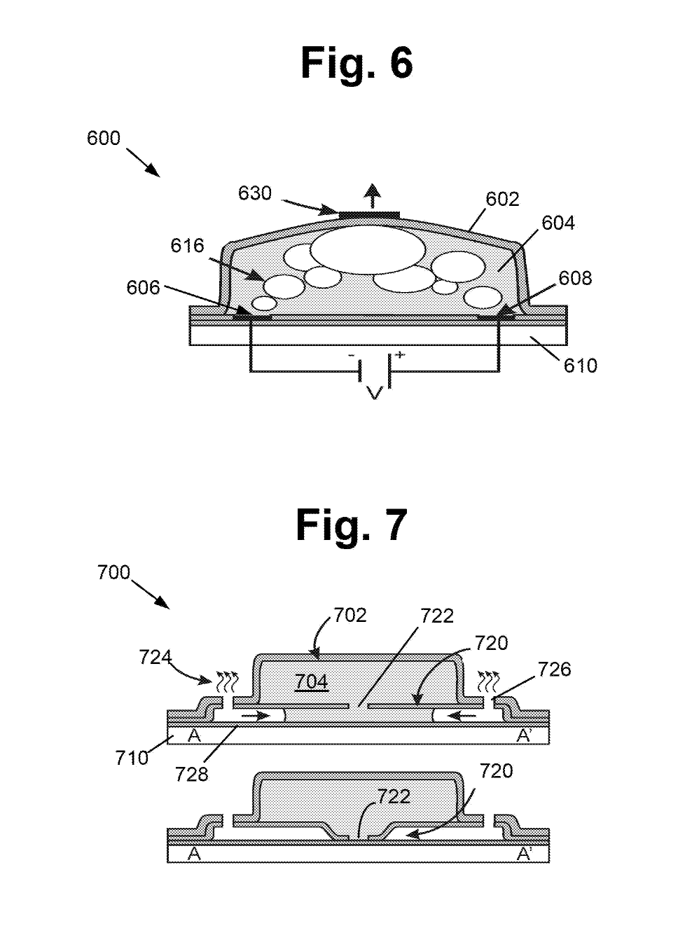

FIG. 6 illustrates an out-of-plane actuator 600, in accordance with exemplary embodiments of the present disclosure. Actuator 600 includes a flexible housing forming a chamber 602 that serves to encapsulate a liquid 604. Device 600 also includes two actuation electrodes 606 and 608, which are partially exposed to the liquid 604 as shown. The housing 602 is shown on a base 610. An applied voltage is shown.

In this configuration the encapsulated electrodes 606, 608 can be utilized to generate electrolytic gas 616, which increases the pressure within the microchamber 602. The top membrane of the chamber 602 is accordingly moved or actuated upwards, which in turn actuates any attached device or structure 630, e.g., an electrode of microelectrode array (MEA).

### C. Exemplary Embodiments

### Stiction Valves

As was stated previously, embodiments of flexible MEMS medical devices according to the present disclosure can include stiction valves to isolate the internal chamber fluid from the external fluidic environment.

FIG. 7 includes two side views showing the principle of operation of a stiction valve of a medical device 700, in accordance with exemplary embodiments of the present disclosure. Device 700 includes a flexible housing forming a chamber 702 for encapsulating a liquid 704. Device 700 is shown having a stiction valve 720 and a substrate 728 on an underlying base surface 710. The top view of FIG. 7 illustrates evaporation 724 through fluidic access ports 726 of the device 700. Evaporation through the access ports 726 moves the liquid fronts along the connecting channels toward the stiction valve 720, as indicated by arrows. The stiction valve central pore or aperture is indicated 722.

In the bottom view of FIG. 7, capillary forces seal the annular plate of the stiction valve 720 against the substrate 728, blocking the central aperture 722, and trapping or encapsulating liquid 704 inside the chamber 702. In this way, the fluid 704 within the chamber 702 can be isolated from the environment external to the device. With appropriate configuration, the medical device 700 can then be used for actuation and/or sensing.

Because force sensing is accomplished electrochemically, the nature of fluid within the chamber is important to sensor calibration. Therefore, if a known fluid is to be used, a stiction valve can be integrated which traps this liquid while the sensor is operated in an environment composed of a separate and distinct liquids (if desired). Force sensing range may be slightly limited in such a configuration because liquid is trapped and is approximately incompressible. The exclusion of a stiction valve enables fluid to flow in and out of the chamber freely. Thus, it is desirable, but not essential, that the environmental fluid be known or characterized in order to calibrate sensor operation in this fluid.

Because actuation is accomplished using electrolytically generated gas, it is possible that some of this gas may escape through the fluidic access ports if enough gas is generated. This can impose a limitation to the amount of pressure which can build in the chamber thereby limiting actuation.

The inclusion of a stiction valve for exemplary embodiments of the present disclosure can solve this problem. Because a stiction valve seals downward towards the substrate, the generation of any pressure in the chamber will serve only to push the valve downward thereby sealing it even more forcefully. This can allow for the generation of high pressures, maximizing actuation.

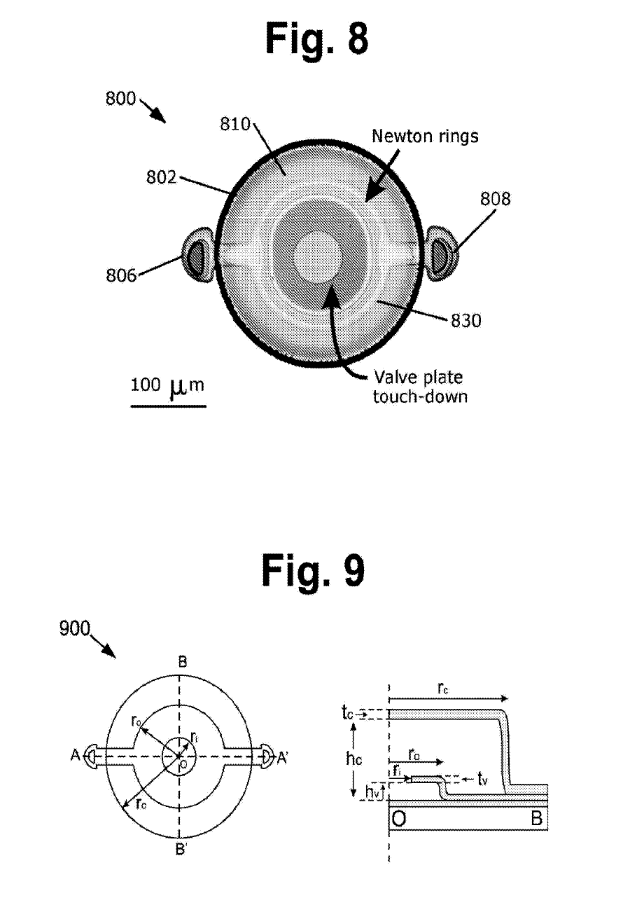

FIG. 8 is an optical photograph of a medical device 800 having a 300 μm diameter chamber and stiction valve that was constructed in accordance with the present disclosure. Device 800 includes a chamber 802, first and second fluid access ports 806, 808, substrate 810, and stiction valve 830. As shown, the chamber 802 is free standing while the valve 830 is collapsed and pinned to a substrate. The dark central region indicates that the annular plate of he valve 830 is lying flat again the substrate while interference (Newton) rings indicate proximity to substrate as plate transitions from contact to freestanding.

FIG. 9 includes top and side-section views of a medical device microchamber 900 with stiction valve, including the layout and key parameters, in accordance with exemplary embodiments. Left: Top-view indicating key radii, Right: Cross-section indicating key heights and thicknesses. Gray coloring indicates Parylene film. Exemplary embodiments were constructed with parameters of FIG. 9 having values as indicated in Table 1, below.

Table 1—Parameters selected for device fabrication. These parameters were used for tested devices; other devices can be fabricated with variations in these dimensions.

TABLE 1

| Parameter | Dimension (μm) |
|---|---|
| rₒ | 100 |
| rᵢ | 35 |
| r_{c} | 150 |
| hᵥ | 2 |
| h_{c} | 12 |
| tᵥ | 2 |
| t_{c} | 4.2 |

### D. Exemplary Embodiments

### Fabrication

For exemplary embodiments, device fabrication can begin with lithographically defined electrodes (e.g., platinum) patterned on a Parylene substrate. An insulation layer of Parylene can then deposited and patterned in an oxygen plasma thereby removing the insulation over the electrodes. A layer of sacrificial material (photoresist) can then be patterned to form the fluidic access ports and optional stiction valve structures. An additional layer of Parylene can then be deposited and patterned to open the access port vias (and stiction valve central pore). Another layer of sacrificial material can then be deposited and patterned (photoresist) to form the chamber structures. This can be followed by a final deposition of Parylene, forming the final chamber structure. A final Parylene etching step can then reopen vias to the fluidic access ports. The sacrificial material can then be dissolved away by a suitable process, e.g., soaking in acetone and IPA followed by DI water. The chamber finally can then be filled with the desired fluid by immersion in a bath of such a fluid.

For actuation purposes, additional steps may be necessary to integrate a device or structure, such as an additional surface electrode. Stiction valve activation can occur by simply exposing the device to ambient conditions. Evaporation through the access ports can cause the valve to seal due to stiction.

Accordingly, aspects and embodiments of the present disclosure can provide benefits and advantages over previous techniques.

The components, steps, features, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, objects, benefits and advantages. These also include embodiments in which the components and/or steps are arranged and/or ordered differently.

For example, while Parylene C has been described as a material for medical devices described herein, other types of parylene and other polymers may be used within the scope of the present disclosure. For example, there are a number of derivatives and isomers of parylene including: Parylene N (hydrocarbon), Parylene C (one chlorine group per repeat unit), Parylene D (two chlorine groups per repeat unit), Parylene AF-4 (generic name, aliphatic flourination 4 atoms), Parylene SF (AF-4, Kisco product), Parylene HT (AF-4, SCS product), Parylene A (one amine per repeat unit, Kisco product), Parylene AM (one methylene amine group per repeat unit, Kisco product), Parylene VT-4 (generic name, fluorine atoms on the aromatic ring), Parylene CF (VT-4, Kisco product), and Parylene X (a cross-linkable version).

Moreover, while embodiments of medical device actuators are described herein as including a device, e.g., electrode, on a movable actuation surface of the device, such devices are optional. Controlled movement or actuation of a surface of a sensor can occur within the scope of the present disclosure.

In addition, while the foregoing description has been given in the context of using two fluidic access ports for chambers/microchambers of medical devices, the use of one or more than two fluidic access ports in included in the scope of the present disclosure.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

All articles, patents, patent applications, and other publications which have been cited in this disclosure are hereby incorporated herein by reference.

The phrase “means for” when used in a claim is intended to and should be interpreted to embrace the corresponding structures and materials that have been described and their equivalents. Similarly, the phrase “step for” when used in a claim is intended to and should be interpreted to embrace the corresponding acts that have been described and their equivalents. The absence of these phrases in a claim mean that the claim is not intended to and should not be interpreted to be limited to any of the corresponding structures, materials, or acts or to their equivalents.

Nothing that has been stated or illustrated is intended or should be interpreted to cause a dedication of any component, step, feature, object, benefit, advantage, or equivalent to the public, regardless of whether it is recited in the claims.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents.

The invention claimed is:

1. An encapsulated-liquid device comprising:
a flexible housing having an interior surface defining a chamber and configured to encapsulate a liquid within the chamber;
first and second fluidic access ports configured to admit liquid into the chamber; and
first and second electrodes, each having a portion exposed to the chamber, wherein the first and second electrodes are configured to sense an impedance of a liquid within the chamber.

2. The device of claim 1 further comprising a stiction valve configured to seal the chamber.

3. The device of claim 2 wherein the housing comprises Parylene.

4. The device of claim 3 wherein the housing comprises Parylene C.

5. The device of claim 2 wherein the first and second fluidic access ports each comprise an internal and external aperture relative to the housing, wherein the internal and external apertures are connected by an access port via.

6. The device of claim 1 wherein the housing is cylindrical and has a diameter from about 25 μm to about 1 mm.

7. The device of claim 2 wherein the housing comprises a substrate and wherein the stiction valve comprises a valve plate with a central aperture, wherein the central aperture is configured to admit liquid from the first and second fluidic access ports to the chamber when the valve plate is not in contact with the substrate.

8. An encapsulated-liquid medical device comprising:
a flexible housing having an interior defining a chamber and configured to encapsulate a liquid within the chamber;
first and second fluidic access ports configured to admit liquid into the chamber;
first and second electrodes, each having a portion exposed to the chamber; and configured to cause electrolysis of a liquid within the chamber; and
at least one electrode disposed on the exterior surface of the housing.

9. The device of claim 8 wherein the wherein at least one electrode comprises a plurality of electrodes.

10. The device of claim 9 wherein the plurality of electrodes is configured as a microelectrode array (MEA).

11. The device of claim 10 wherein the housing comprises Parylene.

12. The device of claim 11 wherein the housing comprises Parylene C.

13. The device of claim 8 further comprising a stiction valve configured to seal the chamber.

14. The device of claim 8 wherein the first and second fluidic access ports each comprise an internal and external aperture relative to the housing, wherein the internal and external apertures are connected by an access port via.

15. The device of claim 8 wherein the housing is cylindrical and has a diameter from about 25 μm to about 1 mm.

16. The device of claim 13 wherein the housing comprises a substrate and wherein the stiction valve comprises a valve plate with a central aperture, wherein the central aperture is configured to admit liquid from the first and second fluidic access ports to the chamber when the valve plate is not in contact with the substrate.

17. A method of positioning a surface relative to a device, wherein the medical device includes (i) a flexible housing having a substrate and an interior defining a chamber configured to encapsulate a liquid within the chamber, (ii) first and second electrodes, each having a portion exposed to the chamber, and (iii) and at least one electrode disposed on the exterior surface of the housing, the method comprising:
applying a voltage potential across the first and second electrodes;
causing electrolysis of a liquid within the chamber; and
moving the exterior surface relative to the substrate.

18. The method of claim 17 wherein the at least one electrode disposed on the exterior surface of the housing comprises a microelectrode array (MEA).

19. The method of claim 17 wherein the device further comprises first and second fluidic access ports configured to admit liquid into the chamber.

20. The method of claim 17 wherein the device further comprises a stiction valve.

21. The method of claim 17, wherein the housing of the medical device comprises parylene.

22. The method of claim 17, further comprising encapsulating liquid within the chamber.

23. A method of sensing force applied to a movable surface of a device, wherein the device includes (i) a flexible housing having a substrate, a moveable surface, and an interior defining a chamber configured to encapsulate a liquid within the chamber, and (ii) first and second electrodes, each having a portion exposed to the chamber, the method comprising:
applying a voltage potential across the first and second electrodes;
in response to a force applied to the movable surface, sensing an impedance change of a liquid within the chamber; and
correlating sensed impedance change of the liquid to the force applied to the moveable surface.

24. The method of claim 23 wherein the device further comprises first and second fluidic access ports configured to admit liquid into the chamber.

25. The method of claim 23 wherein the device further comprises a stiction valve.

26. The method of claim 23, wherein the housing of the device comprises parylene.

27. The method of claim 23, further comprising encapsulating liquid within the chamber.
